(19) United States
(12) Patent Application Publication
(10) Pub. No.: US 2003/0119331 A1
(43) Pub. Date: Jun. 26, 2003

(54) Method for manufacturing semiconductor device

(76) Inventor: Seiji Muranaka, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/151,161

(22) Filed: May 21, 2002

(30) Foreign Application Priority Data
Dec. 20, 2001 (JP) 2001-387387

(51) Int. Cl. H01L 21/302; H01L 21/461

(52) U.S. Cl. 438/748; 438/753; 438/906

(57) ABSTRACT

In the method for removing etching residue adhered on a semiconductor substrate using a stripping liquid containing fluorine, the stripping liquid on the semiconductor substrate can be flung away by rotating the semiconductor substrate after the residue removing treatment. Thereby, the etching of the interlayer insulating film caused between the residue removing treatment and washing with water can be minimized.

### BACKGROUND OF THE INVENTION

1. Field of the Invention

The present invention relates to a method for manufacturing a semiconductor device, and specifically to the removal of a residue adhered when a contact hole is subjected to etching.

2. Background Art

Recently, the number of wiring layers formed on a semiconductor substrate has increased for the higher integration of semiconductor elements. In the process for manufacturing multi-layer wiring, after etching a contact hole for electrically interconnecting wirings in the multi-layer wiring, treatment for removing a residue is performed. Chemicals used for residue removing treatment include a mixture of sulfuric acid and hydrogen peroxide, a mixture of ammonia and hydrogen peroxide, ammonia water, or an organic stripping liquid containing an amine compound that etches a small quantity of an interlayer insulating film.

On the other hand, the change of wiring materials for the downsizing of devices has restricted the kinds of chemicals that can be used for residue removing treatment.

For example, chemical solutions containing hydrogen peroxide cannot be used for tungsten (W) used as a wiring material, and titanium nitride (TiN) used as a barrier metal since chemical solutions containing hydrogen peroxide etch a tungsten film used as a wiring material, and a titanium nitride film used as a barrier metal. When a silicon-based material, such as a silicon (Si) substrate and a polycrystalline silicon (poly-Si) film, is exposed on the bottom of a contact hole, ammonia water cannot be used since ammonia water etches a silicon-based material, such as a silicon substrate and a polycrystalline silicon film.

Therefore, a stripping liquid containing a fluorine-based compound is used in the residue treating process in lieu of chemical solutions containing hydrogen peroxide. Also, from the point of view of the capacity of removing residue, a stripping liquid containing a fluorine-based compound that has a strong power of removing a residue is used.

However, if a stripping liquid containing a fluorine-based compound is used as the chemical solution for removing a residue after etching the contact hole, a problem that the silicon oxide film formed between wiring layers is etched off arises. Therefore, problems such as the expansion and the deformation of the contact hole have arisen.

Particularly when oxide film of different materials are laminated as a interlayer insulating film between multi-layer wirings, since the etching rates of the films differ, steps are formed in the shape of the contact hole after chemical treatment using a stripping liquid containing a fluorine-based compound. Therefore, the shape of the contact hole has been degraded in the sidewall of the contact hole.

When the degradation of the shape of the contact hole occurs, the insulation of the metal film in the contact hole is deteriorated, causing wiring to break, the reliability of wiring to lower, and the serious defect of devices to occur.

### SUMMARY OF THE INVENTION

The present invention is made to solve the above-described problems, and an object of the present invention is to improve the reliability of semiconductor devices by preventing the degradation of the shape of the contact hole when the etching residue is removed after the formation of the contact hole.

According to one aspect of the present invention, there is provided a method for manufacturing a semiconductor device by removing etching residue adhered on a semiconductor substrate using a stripping liquid containing fluorine. The method comprises the following steps. The etching residue is removed by using the stripping liquid. The stripping liquid away is flung by rotating the semiconductor substrate after the step for removing the residue. The semiconductor substrate is washed with water. the semiconductor substrate is dried.

According to another aspect of the present invention, there is provided a method for manufacturing a semiconductor device by removing etching residue adhered on a semiconductor substrate using a stripping liquid containing fluorine. The method comprises the following steps. The composition of the stripping liquid is monitored. Insufficient ingredients of the composition of the stripping liquid is replenished. The etching residue is removed by using the stripping liquid.

According to another aspect of the present invention, there is provided a method for manufacturing a semiconductor device by removing etching residue adhered on a semiconductor substrate using a stripping liquid containing fluorine. The method comprises the following steps. The etching residue is removed by using the stripping liquid. The semiconductor substrate is rinsed by using a rinsing liquid after the step for removing the residue. The semiconductor substrate is washed with water. The semiconductor substrate is dried.

By rotating the semiconductor substrate after the residue removing treatment, the stripping liquid on the semiconductor substrate can be flung away. Thereby, the etching of the interlayer insulating film caused between the residue removing treatment and washing with water can be minimized. Therefore, etching residues can be removed without producing defects such as the enlargement of the contact hole formed on the interlayer insulating film or the deformation of the contact hole.

Since the components of the stripping liquid in the tank is monitored, and the composition is maintained constant, increase of etching due to change in the content of the components in the stripping liquid with the lapse of time can be inhibited. Therefore, the occurrence of defects such as the enlargement of the contact hole formed on the interlayer insulating film or the deformation of the contact hole can be inhibited.

By rinsing the semiconductor substrate after the residue removing treatment, the etching of the interlayer insulating film caused after the residue removing treatment can be minimized. Therefore, the occurrence of defects such as the enlargement of the contact hole formed on the interlayer insulating film or the deformation of the contact hole can be inhibited.

Other and further objects, features and advantages of the invention will appear more fully from the following description.

### BRIEF DESCRIPTION OF THE DRAWINGS

FIG. 1 is a schematic sectional view showing the vicinity of a contact hole formed on the upper surface of a semiconductor substrate, and shows the state after the contact hole has been formed by etching, and before performing residue removing treatment.

FIG. 2 is a flowchart showing the residue removing process according to Embodiment 1.

FIG. 3 is a flowchart showing the steps of residue removing treatment incorporating the step of flinging the stripping liquid away.

FIG. 4 is a flowchart showing the steps of residue removing treatment incorporating the rinsing step.

### DETAILED DESCRIPTION OF THE PREFERRED EMBODIMENTS

Embodiment 1

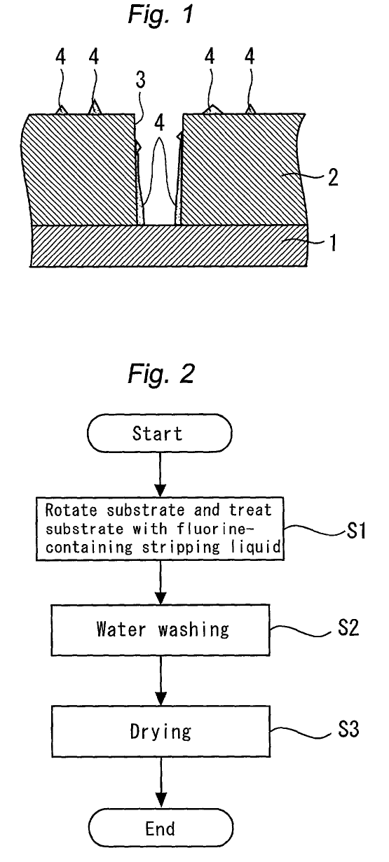

FIG. 1 is a schematic sectional view showing the vicinity of a contact hole formed on the upper surface of a semiconductor substrate, and shows the state after the contact hole has been formed by etching, and before performing residue removing treatment. As shown in FIG. 1, a contact hole 3 is formed by etching in an interlayer insulating film 2 formed on a lower-layer wiring 1. Immediately after the contact hole 3 is formed, etching residues 4 remain. The etching residues 4 are adhered inside the contact hole 3 and on the interlayer insulating film 2.

Since the etching residues 4 interfere with the formation of a conductive film inside the contact hole 3 and on the interlayer insulating film 2, they must be removed by chemical treatment. This residue removing process must be realized while restricting the etching quantity of the interlayer insulating film 2, without causing defects, such as the enlargement and the degradation of the shape of the contact hole 3.

In the residue removing process using a stripping liquid containing a fluorine-based compound according to Embodiment 1, the residues are removed while rotating a semiconductor substrate (wafer). Since spray-type (batch type) or discrete-unit-type cleaners can apply a physical force to the semiconductor substrate so as to rotate the semiconductor substrate when a chemical solution is ejected to the semiconductor substrate, the semiconductor substrate can be rotated in the residue removing process.

FIG. 2 is a flowchart showing the residue removing process according to Embodiment 1. First, treatment for removing etching residues 4 on the semiconductor substrate is performed using a stripping liquid containing a fluorine-based compound while rotating the semiconductor substrate in Step S1. Then, the semiconductor substrate is washed with water to remove the stripping liquid in Step S2, and the semiconductor substrate is dried in Step S3.

By thus performing treatment for removing etching residues while rotating the semiconductor substrate in Step S1, the power to remove the etching residues 4 can be significantly improved compared with residue removal using a cleaner of a multi-tank dip type. Thereby, since the time for chemical treatment for residue removal can be shortened, etching quantity of the interlayer insulating film 2 can be minimized.

In dip-type cleaners, excessive etching takes place during transferring from the stripping liquid tank containing a fluorine-based compound to the water-washing tank, and the contact hole 3 is enlarged or deformed. However, since spray-type or discrete-unit-type cleaners are of one-chamber system, no transfer of wafers between process steps is required. Therefore, excessive etching can be avoided by using spray-type or discrete-unit-type cleaners.

According to Embodiment 1, as described above, the time for chemical treatment using a stripping liquid can be shortened by rotating the semiconductor substrate in the process of residue removing treatment, the etching quantity of the interlayer insulating film 2 can be reduced. Therefore, etching residues 4 can be removed without producing defects such as the enlargement of the contact hole 3 formed on the interlayer insulating film 2 or the deformation of the contact hole 3.

Embodiment 2

In Embodiment 2, a step of residue removing treatment with a stripping liquid containing a fluorine-based compound, and a step of flinging the stripping liquid away by rotating the semiconductor substrate at a high speed before the following step of washing with water are performed when residue removing treatment is performed using spray-type or discrete-unit-type cleaners. By performing the step of flinging the stripping liquid away after the step of residue removing treatment with the stripping liquid containing a fluorine-based compound, etching that takes place after the treatment using the stripping liquid to washing with water, and etching that takes place in the initial stage of washing with water can be inhibited.

Here, conditions for rotating the semiconductor substrate in the step of flinging the stripping liquid away are preferably a rotation speed of 800 rpm or higher, and a time of 5 seconds or longer. The treatment for 10 seconds at a rotation speed of 2000 rpm is more preferable. Thereby the stripping liquid adhered to the semiconductor substrate can be completely flung away.

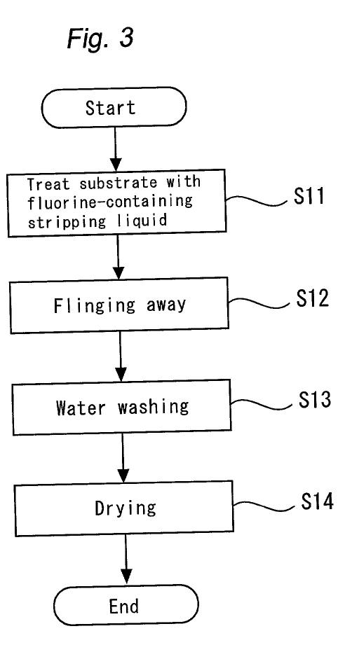

FIG. 3 is a flowchart showing the steps of residue removing treatment incorporating the step of flinging the stripping liquid away. First, etching residues 4 on the semiconductor substrate is removed using a stripping liquid containing a fluorine-based compound in Step S11. Then, the semiconductor substrate is rotated for about 10 seconds at a rotation speed of 2000 rpm to fling stripping liquid away in Step S12. Then, the semiconductor substrate is washed with water to remove the stripping liquid in Step S13, and the semiconductor substrate is dried in Step S14.

According to Embodiment 2, as described above, the stripping liquid on the semiconductor substrate can be flung away by rotating the semiconductor substrate after the step of removing the residues. Thereby, etching of the interlayer insulating film 2 that takes place between the step of removing the residues and the step of washing with water can be minimized. Therefore, etching residues 4 can be removed without producing defects such as the enlargement of the contact hole 3 formed on the interlayer insulating film 2 or the deformation of the contact hole 3.

Embodiment 3

In Embodiment 3, when residue removing treatment is performed using a spray-type or discrete-unit-type cleaner, the flow rate of water for washing the semiconductor substrate after treatment using a stripping liquid is increased to control etching during the initial stage of washing. Although the steps of the treatment are same as in Embodiment 1, the quantity of water for washing the semiconductor substrate in Step S3 is increased.

By thus increasing the flow of water in the initial stage of washing with water, the etching quantity of the interlayer insulating film 2 can be controlled effectively. In this case, the typical value of the increased flow rate of water is preferably about 20 liters/minute. Since the flow rate of water in an ordinary spray-type cleaner is generally 10 liters/minute, doubling the flow rate to about 20 liters/minute surely controls etching. More preferably, increase in the quantity of water to about 30 liters/minute can control etching better. Thereby etching in the initial stage of washing with water can be surely controlled. Here, although etching can be controlled by increasing the flow rate of water only in the initial stage of washing, etching can be controlled more preferably by increasing the flow rate of water continuously throughout the time for washing with water.

According to Embodiment 3, as described above, increase in the quantity of water for washing after the process of residue removing treatment can surely control etching in the initial stage of washing. Therefore, etching residues 4 can be removed without producing defects such as the enlargement of the contact hole 3 formed on the interlayer insulating film 2 or the deformation of the contact hole 3.

Embodiment 4

In the case of a spray-type (batch-type) cleaner that recycles the stripping liquid, if water in the stripping liquid containing a fluorine-based compound evaporates with the lapse of time, the concentration of the liquid elevates, and the etching quantity increases. In Embodiment 4, the process is controlled so that the increase of etching with the lapse of time is inhibited by reducing the purge of the stripping-liquid tank and the purge quantity in the chamber to restrict the evaporating quantity of water.

In addition, the composition of the stripping liquid is monitored, and the insufficient component due to change is replenished, or the fresh stripping liquid is added. Thereby, the change of the etching quantity due to the change of liquid composition with the laps of time can be prevented. As the method for monitoring liquid composition, the measurement of conductivity of the stripping liquid, or the measurement of absorption coefficient of the stripping liquid can be used.

An ordinary fluorine-based stripping liquid contains three major components: a fluorine-based compound, several types of organic solvents, and water. In the method for replenishing insufficient components due to change, the content of each component in the stripping liquid is measured, and only the components that have become insufficient are replenished. In this method, each of a plurality of components is independently replenished. For example, only the insufficient fluorine-based compound is replenished, or only insufficient water is replenished.

The method to replenish a fresh stripping liquid is a method to replenish the total quantity of the stripping liquid lost by lot treatment, circulation or evaporation. In this method, a fresh stripping liquid containing all of the above-described components is added without modification. In this method, the measurement of the components is not required, and only the quantity of the stripping liquid that has become insufficient is measured. Since the type of cleaners does not limit the method for maintaining the composition of the stripping liquid according to Embodiment 4, this method can be applied to various types of cleaners, such as the spray-type cleaner, the discrete-unity-type cleaner, and the dip-type multi-tank cleaner.

According to Embodiment 4, as described above, since the components of the stripping liquid in the tank are monitored, and the composition is maintained constant, the increase of etching quantity due to change in the content of the components in the stripping liquid can be minimized. Therefore, etching residues 4 can be removed without producing defects such as the enlargement of the contact hole 3 formed on the interlayer insulating film 2 or the deformation of the contact hole 3.

Embodiment 5

In Embodiment 5, the stripping liquid adhered on the semiconductor substrate is replaced before washing with water after chemical treatment. As a method for replacing the stripping liquid, rinsing with an organic solvent contained in the stripping liquid is performed between the steps of chemical treatment and washing with water.

By thus providing the rinsing step between the steps of chemical treatment and washing with water, etching can be inhibited between the completion of chemical treatment and the start of washing with water, or the time when the stripping liquid is completely removed from the wafer by washing with water in the initial step of washing.

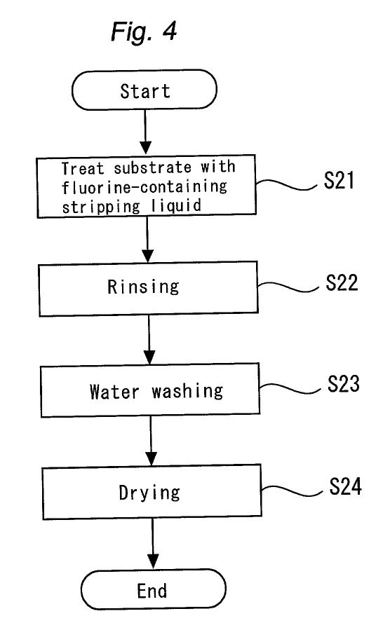

FIG. 4 is a flowchart showing the steps of residue removing treatment incorporating the rinsing step. First, etching residues 4 on the semiconductor substrate is removed using a stripping liquid containing a fluorine-based compound in Step S21. Then, the semiconductor substrate is rinsed using the organic solvent contained in the stripping liquid in Step S22. Then, the semiconductor substrate is washed with water to remove the stripping liquid in Step S23, and the semiconductor substrate is dried in Step S24.

Since the type of cleaners does not limit the method for incorporating the rinsing step according to Embodiment 5, this method can be applied to various types of cleaners, such as the spray-type cleaner, the discrete-unity-type cleaner, and the dip-type multi-tank cleaner.

As the rinsing liquid used in Step S22, the organic solvent contained in the stripping liquid used in Step S21, or the mixed solvent of IPA (isopropyl alcohol) and water is used. Since IPA itself reacts with a fluorine-based compound to produce precipitates, it cannot be used as the rinsing liquid. Therefore, water must be added to IPA, and the mixing ratio is preferably 50 to 90% by volume of IPA with respect to the entire rinsing liquid and the balance being water.

According to Embodiment 5, as described above, since the semiconductor substrate is rinsed after the residue removing treatment, the etching of the interlayer insulating film 2 caused after the residue removing treatment can be minimized. Therefore, etching residues 4 can be removed without producing defects such as the enlargement of the contact hole 3 formed on the interlayer insulating film 2 or the deformation of the contact hole 3.

Although a stripping liquid containing fluorine is used in the above-described embodiments as the stripping liquid used for the residue removing treatment, the present invention is not limited to such a stripping liquid, but can be widely applied to the stripping liquids that etch the interlayer insulating film 2 excessively.

Beside the claimed invention, the present invention includes various aspects as described above and summarized as follows.

According to one aspect of the present invention, there is provided a method for manufacturing a semiconductor device by removing etching residue adhered on a semiconductor substrate using a stripping liquid containing fluorine. The method comprises the following steps. The etching residue is removed by using the stripping liquid. The stripping liquid away is flung by rotating the semiconductor substrate after the step for removing the residue. The semiconductor substrate washed with water. The semiconductor substrate dried.

According to another aspect of the present invention, there is provided a method for manufacturing a semiconductor device by removing etching residue adhered on a semiconductor substrate using a stripping liquid containing fluorine. The method comprises the following steps. The etching residue is removed by using the stripping liquid. The semiconductor substrate is rinsed by using a rinsing liquid after the step for removing the residue. The semiconductor substrate is washed with water. The semiconductor substrate is dried. Effect of the Invention

Since the present invention is constituted as described above, the following effects are obtained.

By rotating the semiconductor substrate in the residue removing treatment, the time for chemical treatment using the stripping liquid can be shortened, and the etching quantity of the interlayer insulating film can be reduced. Therefore, etching residues can be removed without producing defects such as the enlargement of the contact hole formed on the interlayer insulating film or the deformation of the contact hole, and the reliability of the semiconductor device can be improved.

By rotating the semiconductor substrate after the residue removing treatment, the stripping liquid on the semiconductor substrate can be flung away. Thereby, the etching of the interlayer insulating film caused between the residue removing treatment and washing with water can be minimized. Therefore, etching residues can be removed without producing defects such as the enlargement of the contact hole formed on the interlayer insulating film or the deformation of the contact hole.

By increasing the quantity of water for washing after the residue removing treatment, etching in the initial stage of washing can be surely inhibited. Therefore, defects such as the enlargement of the contact hole formed on the interlayer insulating film or the deformation of the contact hole can be prevented.

Since the components of the stripping liquid in the tank is monitored, and the composition is maintained constant, increase of etching due to change in the content of the components in the stripping liquid with the lapse of time can be inhibited. Therefore, the occurrence of defects such as the enlargement of the contact hole formed on the interlayer insulating film or the deformation of the contact hole can be inhibited.

By rinsing the semiconductor substrate after the residue removing treatment, the etching of the interlayer insulating film caused after the residue removing treatment can be minimized. Therefore, the occurrence of defects such as the enlargement of the contact hole formed on the interlayer insulating film or the deformation of the contact hole can be inhibited.

By using the organic solvent contained in the stripping liquid as the rinsing liquid, the stripping liquid on the semiconductor substrate can be surely replaced.

By using an aqueous solution of isopropyl alcohol as the rinsing liquid, the stripping liquid on the semiconductor substrate can be surely replaced.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-387387, filed on Dec. 20, 2001 including specification, claims, drawings and summary, on which the Convention priority of the present application is based, are incorporated herein by reference in its entirety.

1. A method for manufacturing a semiconductor device by removing etching residue adhered on a semiconductor substrate using a stripping liquid containing fluorine comprising the steps of:
removing said etching residue using said stripping liquid,
flinging said stripping liquid away by rotating said semiconductor substrate after said step for removing said residue,
washing said semiconductor substrate with water, and
drying said semiconductor substrate.

2. A method for manufacturing a semiconductor device by removing etching residue adhered on a semiconductor substrate using a stripping liquid containing fluorine comprising the steps of:
monitoring the composition of said stripping liquid,
replenishing insufficient ingredients of said composition of the stripping liquid, and
removing said etching residue using said stripping liquid.

3. A method for manufacturing a semiconductor device by removing etching residue adhered on a semiconductor substrate using a stripping liquid containing fluorine comprising the steps of:
removing said etching residue using said stripping liquid,
rinsing said semiconductor substrate using a rinsing liquid after said step for removing said residue,
washing said semiconductor substrate with water, and
drying said semiconductor substrate.

4. The method for manufacturing a semiconductor device according to claim 3, wherein said rinsing liquid comprises an organic solvent that is an ingredient of said stripping liquid.

5. The method for manufacturing a semiconductor device according to claim 3, wherein said rinsing liquid comprises an aqueous solution of isopropyl alcohol.

6. The method for manufacturing a semiconductor device according to claims 3, wherein said semiconductor substrate is rotated in the step of removing said etching residue.

7. The method for manufacturing a semiconductor device according to claim 4, wherein said semiconductor substrate is rotated in the step of removing said etching residue.

8. The method for manufacturing a semiconductor device according to claims 5, wherein said semiconductor substrate is rotated in the step of removing said etching residue.
